(19) United States
(12) Patent Application Publication
(10) Pub. No.: US 2012/0322192 A1
(43) Pub. Date: Dec. 20, 2012

(54) METHOD OF DEFECT REDUCTION IN ION IMPLANTED SOLAR CELL STRUCTURES

(75) Inventors: John Graff, Swampscott, MA (US); Nicholas Bateman, Reading, MA (US)

(73) Assignee: VARIAN SEMICONDUCTOR EQUIPMENT ASSOCIATES, INC., Gloucester, MA (US)

(21) Appl. No.: 13/160,580

(22) Filed: Jun. 15, 2011

(51) Int. Cl. H01L 31/18

(52) U.S. Cl. 438/58; 257/E31.002

(57) ABSTRACT

An improved solar cell is disclosed. To create the internal p-n junction, one surface of the substrate is implanted with ions. After the implantation, the substrate is thermally treated. The thermal process distributes the dopant throughout the substrate, while repairing crystal damage caused by implantation. After the thermal process, residual crystal damage may remain, which adversely impacts solar cell efficiency. In order to further reduce the residual damage, the uppermost portion of the surface is then removed, thereby eliminating that portion of the substrate where most of the defects reside. The lower defect concentration reduces recombination and improves efficiency of the solar cell.

### BACKGROUND

Ion implantation is a standard technique for introducing conductivity-altering impurities into a workpiece. A desired impurity material is ionized in an ion source, the ions are accelerated to form an ion beam of prescribed energy, and the ion beam is directed at the surface of the workpiece. The energetic ions in the beam penetrate into the bulk of the workpiece material and are embedded into the crystalline lattice of the workpiece material to form a region of desired conductivity.

Solar cells are one example of a device that uses silicon workpieces. Any reduced cost to the manufacture or production of high-performance solar cells or any efficiency improvement to high-performance solar cells would have a positive impact on the implementation of solar cells worldwide. This will enable the wider availability of this clean energy technology.

A semiconductor solar cell is a simple device having an in-built electric field that separates the charge carriers generated through the absorption of photons in the semiconductor material. This electric field is typically created through the formation of a p-n junction (diode) which is created by differential doping of the semiconductor material. Doping a part of the semiconductor substrate (e.g. surface region) with impurities of opposite polarity forms a p-n junction that may be used as a photovoltaic device converting light into electricity.

FIG. 1 shows a cross section of a representative solar cell 100, where the p-n junction 120 is located away from the illuminated surface. Photons 10 enter the solar cell 100 through the top (or illuminated) surface, as signified by the arrows. These photons pass through an anti-reflective coating 104, designed to maximize the number of photons that penetrate the substrate 100 and minimize those that are reflected away from the substrate. The ARC 104 may be comprised of an SiNₓ layer. Beneath the ARC 104 may be a passivation layer 103, which may be composed of silicon dioxide. Of course, other dielectrics may be used. On the back side of the solar cell 100 are an aluminum emitter region 106 and an aluminum layer 107. Such a design may be referred to as an Al back emitter cell in one instance.

Internally, the solar cell 100 is formed so as to have a p-n junction 120. This junction is shown as being substantially parallel to the bottom surface of the solar cell 100, although there are other implementations where the junction may not be parallel to the surface. In some embodiments, the solar cell 100 is fabricated using an n-type substrate 101. The photons 10 enter the solar cell 100 through the n+ doped region, also known as the front surface field (FSF) 102. The photons with sufficient energy (above the bandgap of the semiconductor) are able to promote an electron within the semiconductor material's valence band to the conduction band. Associated with this free electron is a corresponding positively charged hole in the valence band. In order to generate a photocurrent that can drive an external load, these electron-hole (e-h) pairs need to be separated. This is done through the built-in electric field at the p-n junction 120. Thus, any e-h pairs that are generated in the depletion region of the p-n junction 120 get separated, as are any other minority carriers that diffuse to the depletion region of the device. Since a majority of the incident photons 10 are absorbed in near surface regions of the solar cell 100, the minority carriers generated in the emitter need to diffuse to the depletion region and get swept across to the other side.

Some photons 10 pass through the front surface field 102 and enter the p-type emitter 106. These photons 10 can then excite electrons within the p-type emitter 106, which are free to move into the front surface field 102. The associated holes remain in the emitter 106. As a result of the charge separation caused by the presence of this p-n junction 120, the extra carriers (electrons and holes) generated by the photons 10 can then be used to drive an external load to complete the circuit.

By externally connecting the base through the front surface field 102 to the emitter 106 through an external load, it is possible to conduct current and therefore provide power. To achieve this, contacts 105, typically metallic and in some embodiments silver, are placed on the outer surface of the front surface field 102.

Several parameters affect the efficiency of a solar cell. For example, any carriers that are generated, but recombine before reaching the p-n junction, negatively impact the performance of the cell. Therefore, there is a need in the art for an improved solar cell to help maximize the number of minority carriers that are swept across the p-n junction, thereby maximizing the energy that can be produced from incident photons.

### SUMMARY

An improved solar cell is disclosed. To create the internal p-n junction, one surface of the substrate is implanted with ions. After the implantation, the substrate is thermally treated. The thermal process distributes the dopant throughout the substrate, while drawing defects closer to the surface. The uppermost portion of the surface is then removed, thereby eliminating that portion of the substrate where most of the defects reside. The lower defect concentration reduces recombination and improves efficiency of the solar cell, while minimally impacting the dopant concentration.

### BRIEF DESCRIPTION OF THE DRAWINGS

For a better understanding of the present disclosure, reference is made to the accompanying drawings, which are incorporated herein by reference and in which:

FIG. 1 is a cross-sectional side view of a solar cell of the prior art;

FIG. 2 is a graph showing the effects of varying implant energy, anneal time and anneal temperature on defect concentration;

FIG. 3 is a graph showing defect concentration versus depth for boron implants of different implant energies;

FIG. 4 is a graph showing dopant concentration versus depth for boron implants of different implant energies; and

FIG. 5 illustrates a manufacturing sequence.

### DETAILED DESCRIPTION

The embodiments of the solar cell are described herein in connection with an ion implanter. Beamline ion implanters, plasma doping ion implanters, or flood ion implanters may be used. In addition, other implant systems may be used. For example, an ion implanter without mass analysis or a plasma tool that focuses ions by modifying the plasma sheath may also be used. An ion beam that is focused to only implant specific portions of the solar cell, or grid-focused plasma systems can also be used for the embodiments disclosed herein. However, the gaseous diffusion, furnace diffusion, laser doping, other plasma processing tools, or other methods known to those skilled in the art may be used. In addition, while implant is described, deposition of the doped layers also can be performed. Also, while specific n-type and p-type dopants are listed, other n-type or p-type dopants may be used instead and the embodiments herein are not limited solely to the dopant listed. Thus, the invention is not limited to the specific embodiments described below.

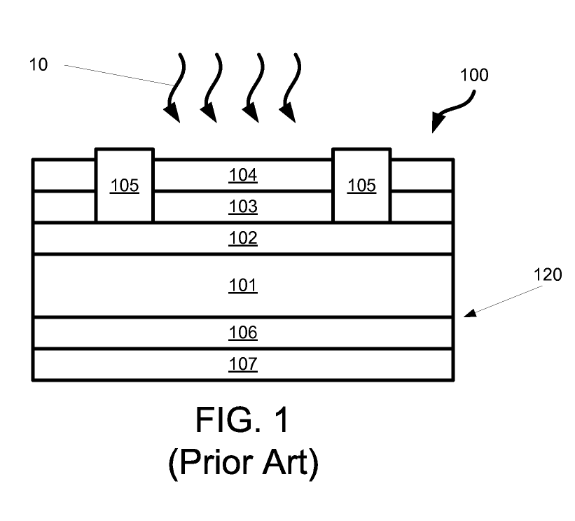

One method used to form the p-n junctions described above is the use of ion implantation. The introduction of p-type dopants to one surface of an n-type substrate creates the internal p-n junction needed for the solar cell. For example, referring to FIG. 1, the emitter 106 may be formed through ion implantation of p-type dopants, such as boron. In addition, the FSF 102 may be created by implanting n-type dopants, such as phosphorus into the opposite surface of the substrate.

It is well known that the implantation of ions into crystalline silicon causes defects, such as vacancies and interstitials. Vacancies are crystal lattice points unoccupied by an atom. This is typically caused when an ion collides with an atom located in the crystal lattice, resulting in transfer of a significant amount of energy to the atom, allowing it to leave its crystal site. Interstitials result when these displaced atoms, or the implanted ions, come to rest in the solid, but do not find a vacant space in the lattice in which to reside. These point defects can migrate and cluster with each other, resulting in dislocation loops and other defects.

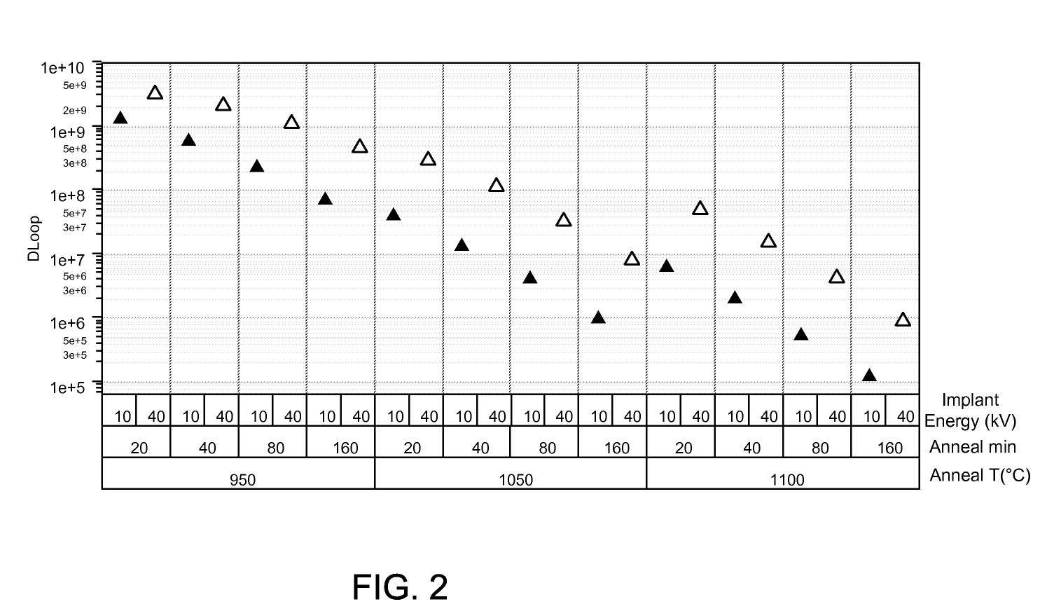

To remove these defects, it is common to perform a thermal process on the substrate, such as an anneal cycle. The temperature of the anneal cycle and its duration both strongly affect the defects which remain in the substrate. For example, FIG. 2 shows a graph showing the effects of implant energy, anneal temperature and anneal time on defect concentration. This data was based on a boron implant at a dose of 1.5e15 cm⁻².

The solid triangles represent the defect concentration when the boron implants were performed at an implant energy of 10 kV. Note that for a given anneal temperature, longer duration anneal cycles always result in a reduction of defects. Similarly, an increase in anneal temperature will remove more defects for a fixed duration. Thus, a high temperature 1100° C. anneal, performed for 160 minutes results in a four order of magnitude reduction in the defect concentration for an implant energy of 10 kV.

The hollow triangles represent the defect concentration when the boron implants were performed at an implant energy of 40 kV. In general, higher implant energy results in more defects for a particular anneal temperature and duration. However, the effects of anneal temperature and anneal duration remain very important, as an increase in either or both of these parameters decreases defect concentration. While it is known that anneal processes will help minimize defects, increased anneal times and temperatures often result in higher manufacturing costs and lower production throughput.

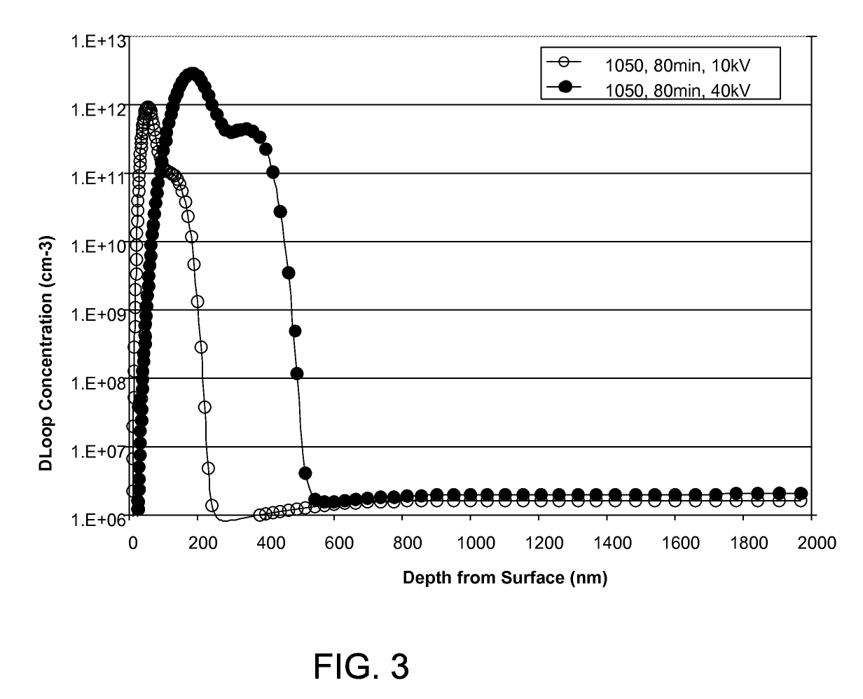

Furthermore, the defect concentration is not uniform as a function of depth. FIG. 3 shows a graph of defect concentration as a function of depth from the surface of the substrate. The hollow circles represent the defect concentration when a boron implant is performed with an implant energy of 10 kV. Following the implant, an anneal cycle is performed at 1050° C. for 80 minutes. From FIG. 3, it is clear that the concentration of defects is much greater near the surface of the substrate. In fact, at a depth of 200 nm below the surface, the defect concentration decreases about 6 orders of magnitude from its maximum value.

The solid circles represent the defect concentration for a boron implant performed with an ion implant energy of 40 kV. Although the high defect concentration extends deeper into the substrate, it is noted that the defect concentration at a depth of 500-600 nm is more than 6 orders of magnitude less than the maximum defect concentration.

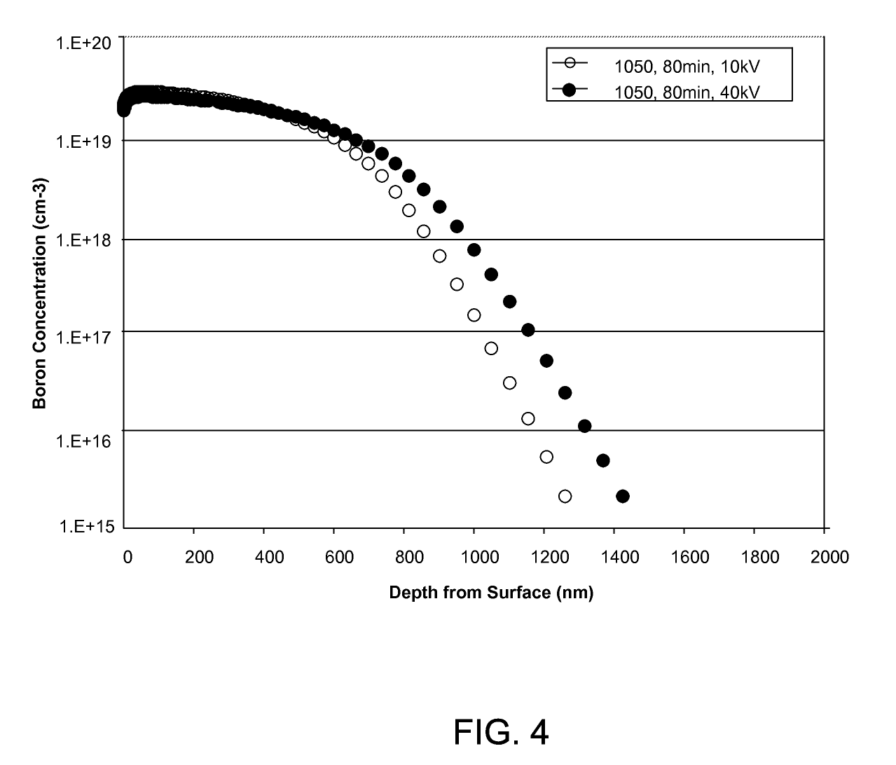

FIG. 4 shows a graph of dopant concentration for the two test cases described above. The hollow circles represent the boron implant at an implant energy of 10 kV. It is noted that at a depth of about 800 nm, the dopant concentration is still greater than 1E18, and at a depth of about 1000 nm, the dopant concentration is still greater than 1E17. Similarly, the solid circles represent the boron implant at an implant energy of 40 kV. It is noted that at a depth of about 1000 nm, the dopant concentration is still greater than 1E18, and at a depth of about 1200 nm, the dopant concentration is till greater than 1E17.

Comparing the graphs of FIG. 3 and FIG. 4, the depth profiles are very different. Specifically, the dopant concentration profile, shown in FIG. 4, decays much more slowly as a function of depth than the defect concentration profile, shown in FIG. 3. In other words, with respect to the lower energy implant, the depth profile from 200 nm to 1000 nm has a defect concentration of less than 1E6, while having a dopant concentration of at least 1E17. Similarly, with respect to the higher energy implant, the depth profile from about 500 nm to 1200 nm also has a defect concentration of less than 1E6, while having a dopant concentration of at least 1E17.

Thus, by removing a portion of the substrate near the surface, the defect concentration can be dramatically reduced, while having a negligible affect on dopant concentration of the substrate.

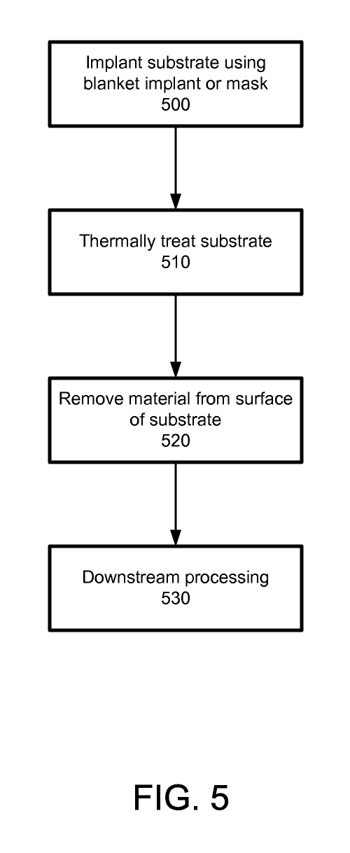

FIG. 5 shows one embodiment of a manufacturing process. First the substrate is implanted with a dopant, such as boron, as shown in step 500. The substrate is then thermally treated to activate the dopants and repair crystal damage, as shown in step 510. After this step, most of the dopants are electrically active, and the residual defect concentration is similar to that shown in FIG. 3. After the substrate is implanted with a dopant and thermally treated, a portion of the implanted surface is removed, as shown in step 520. In one embodiment, the thickness of the substrate material to be removed is related to the implant energy. For example, at lower implant energies, a shallower thickness may be excised. At higher implants, a greater thickness of material must be removed to eliminate the majority of the defects. In some embodiments, a thickness of between 100 nm and 600 nm is removed. In other embodiments, a fixed thickness of substrate material is removed, independent of implant energy. After the defect removal step is performed, the cell continues with downstream processing (Step 530) which may include passivation, metallization, or other appropriate processing steps.

This material can be removed using any of several methods, including but not limited to wet chemical etching, dry etching (i.e. plasma etching), sputtering or oxidation, whereby the substrate is subjected to an oxidizing environment, and the surface layer is consumed by the oxidation.

While this disclosure describes the defects and dopant concentration with respect to boron, the disclosure is not limited to this embodiment. In fact, similar graphs are possible using other p-type dopants, including Type III elements and molecular ions containing Type III elements, such as BF₂. In addition, similar graphs are possible using n-type dopants, including Type V elements and molecular ions containing Type V elements, such as PH₃. In fact, any p-type or n-type layers in a solar cell embodiment may be formed using ion implantation. Therefore, the method described herein can be used when forming the emitter 106 or the FSF 102.

In some solar cell embodiments, there may be additional doped regions. For example, some solar cells utilize selective emitters and selective front surface fields to enhance the attachment to the metal contact. In addition, interdigitated back contact (IBC) solar cells are front surface fields and back surface fields which may be implanted using selective or patterned implants. Unlike the regions described above, these fields are positioned in only a portion of the surface, and are therefore implanted using a patterned or selective implant. In these embodiments, the doped regions are created by using a mask, such as a shadow mask which is placed between the substrate and the ion beam, as shown in step 500. This mask selectively allows ions to reach and implant only certain portions of the substrate. After the implantation is completed, a thermal process (step 510) is performed to activate the dopant and repair the damage caused by the implant process. After the thermal process, the material removal process (step 520) is used to remove a thickness from the substrate, including those regions which were not implanted by the patterned implant. In some embodiments, the material removal process is followed by a downstream process, as shown in step 530. This may be performed to create contacts, such as metal fingers for the FSF or emitter.

Thus, the ion implantation of step 500 may be selective or blanket depending on the particular design of the p-type or n-type region. For example, as described above, selective emitters and selective front side field regions may be created using a selective or patterned ion implantation. Emitter 106 and front side field 102 may be created using blanket implants.

In one embodiment, one surface of an n-type substrate is implanted with boron ions to create a p-type emitter. The opposite surface may optionally be implanted with an n-type dopant, such as a Group V element, to create an n-type front surface field. Following these implants, an anneal cycle may be performed to minimize the damage caused in the substrate. After the anneal process is complete, the substrate is then exposed to a material removal process, such as those described above. This material removal process may be performed sequentially on the two surfaces. In another embodiment, the material removal process is performed on both surfaces simultaneously. The amount of material removed may be related to the implant energy of the implant, or may be a fixed predetermined amount, such as 200 nm.

In another embodiment, ion implantation is used to form selective emitters on which the metal contacts are applied. In many embodiments, this is a selective, or patterned implant, performed using a mask, such as a shadow mask, as shown in step 500. Following the ion implantation and subsequent anneal cycle (step 510), material from the entire surface of the substrate can be removed, including the regions which were not implanted (step 520).

While the disclosure describes the use of anneal of a method to reduce defects, it is understood that any thermal process may be used to reduce defects in the implanted substrate.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of producing a solar cell using a substrate having a first surface and a second surface, comprising:
implanting ions of a first species into a region of said first surface of said substrate;
performing a thermal treatment on said substrate after said implanting to activate the implanted dopants and repair crystal damage; and
removing a thickness of material from said first surface of said substrate after said thermal treatment in order to remove residual crystal damage left over after said thermal treatment.

2. The method of claim 1, wherein said first species comprises a p-type dopant.

3. The method of claim 1, wherein said first species comprises an n-type dopant.

4. The method of claim 1, wherein said region comprises the entirety of said first surface.

5. The method of claim 4, wherein said region is implanted with a first species comprising p-type dopant to form an emitter.

6. The method of claim 4, wherein said region is implanted with a first species comprising n-type dopant to form a front surface field.

7. The method of claim 1, wherein said region comprises less than the entirety of said first surface, and said implanting is performed through a mask.

8. The method of claim 7, wherein said region is implanted to form a selective front surface field, a back surface field or a selective emitter.

9. The method of claim 1, wherein said ions are implanted with an implant energy and said thickness that is removed is related to said implant energy.

10. The method of claim 1, wherein said thickness that is removed is between 100 nm and 600 nm.

11. The method of claim 1, wherein said thermal treatment comprises an anneal.

12. The method of claim 1, wherein said removal of material is performed by a process selected from the group consisting of chemical wet etch, dry etch, oxidation and sputtering.

13. The method of claim 1, further comprising implanting ions of a second species into a region of said second surface of said substrate.

14. The method of claim 13, wherein said thermal treatment is performed after said first surface and said second surface are implanted.

15. The method of claim 13, wherein further comprising removing a thickness of material from said second surface.

16. The method of claim 15, wherein said removing of material from said first side is performed simultaneously with said removing of material from said second side.

17. The method of claim 1, wherein a metallization step is performed on said first surface after said removing step.

18. A method of producing a solar cell using a substrate having a first surface and a second surface, comprising:
implanting ions of a p-type dopant into said first surface of said substrate;
implanting ions of a n-type dopant into said second surface of said substrate;
performing an anneal cycle on said substrate after said implanting to activate the implanted dopants and repair crystal damage; and
removing a thickness of material from said first surface of said substrate and said second surface of said substrate after said thermal treatment in order to remove residual crystal damage left over after said thermal treatment.

19. The method of claim 18, wherein said removing step is performed simultaneously on said first surface and said second surface.

20. A method of producing a solar cell using a substrate having a first surface and a second surface, comprising:
implanting ions of a dopant into a portion of said first surface of said substrate, using a mask;
performing an anneal cycle on said substrate after said implanting to activate the implanted dopants and repair crystal damage;
removing a thickness of material of between 100 nm and 600 nm, from the entirety of said first surface of said substrate after said thermal treatment in order to remove residual crystal damage left over after said thermal treatment; and
performing a metallization step on said implanted portion of said first surface to create contacts.
